(19) United States
(12) Patent Application Publication
(10) Pub. No.: US 2026/0353022 A1
(43) Pub. Date: Nov. 5, 2026

(54) METHOD AND SYSTEM OF AUTOMATIC VOLUME CONTROL FOR SPEAKER SYSTEM

(71) Applicant: HARMAN INTERNATIONAL INDUSTRIES, INCORPORATED, Stamford, CT (US)

(72) Inventors: Zhengmin WANG, Shenzhen, Guangdong (CN); Jianwen ZHENG, Shenzhen, Guangdong (CN); Hongfei ZHOU, Shenzhen, Guangdong (CN)

(73) Assignee: HARMAN INTERNATIONAL INDUSTRIES, INCORPORATED, Stamford, CT (US)

(21) Appl. No.: 19/488,057

(22) PCT Filed: May 26, 2023
(86) PCT No.: PCT/CN2023/096453

§ 371 Date: Nov. 25, 2025

(51) Int. Cl. H04R 29/00; H04R 3/04

(52) U.S. Cl. CPC H04R 29/001; H04R 3/04; H04R 2410/05; H04R 2430/01; H04R 2499/13

(57) ABSTRACT

This disclosure provides a method and a system of automatic volume control for a speaker system. The method may comprise obtaining a microphone input signal including a plurality of frames; performing a filter processing on the micro-phone input signal to obtain the filtered microphone input signal; estimating an energy value for each frame of the filtered microphone input signal; constructing a first set of data consisting of estimated energy values of a predefined number of frames of the filtered microphone input signal; determining a gain coefficient based on the estimated energy values in the first set; and performing the volume control based on the gain coefficient.

### TECHNICAL FIELD

The present disclosure relates to signal processing, and specifically relates to an optimized method and a system of automatic volume control for a speaker based on noise energy estimation.

### BACKGROUND

As we all know, the loudness of equipment sound and the sound quality of a speaker can be affected by ambient noise. What's worse, the sound playback by the speaker may be drowned out if the ambient noise is higher enough. Listeners can't hear the music clearly, which leads to a poor sound quality experience. The listening signal-to-noise rate of users is easily affected by ambient noise like wind noise, especially when portable speakers on the vehicle (such as bicycles, motorbikes, cars and so on) are exposed to the environment where the vehicles are moving rapidly.

Wind noise is actually an aerodynamic noise generated by the impact, friction and airflow gyration between a rapid flow of air and an object when the object is moving. In other words, wind noise is caused by turbulent airflow around surface features. Wind noise is a fast changing and non-stationary noise signal around edges of an object. The greater the wind speed, the higher the wind noise. More specifically, the sound pressure rises with the increasing wind speed and the trend of wind noise spectrum attenuates with the increasing frequency. Based on the existing research on wind noise, it is found that the latter dependency is significant to explain the low-frequency energy distribution of wind noise. Moreover, it is found that the turbulence-shear interaction corresponds to the low frequency response in the wind noise spectrum.

For most speakers on the vehicle, users have to increase a volume table manually if there is much ambient noise around. It is inconvenient and not intelligent. Moreover, it is very dangerous for users to adjust the speaker's volume table while riding. As for speakers on some vehicles like cars, the volume table of speakers in the car can be adjusted automatically but it is correlative to a wheel rotation speed of the vehicle. The wheel rotation speed of the vehicle raises, the volume table increases. This method is based on an assumption that the noise inside the car is strongly correlative to vehicle wheel rotation speed. This method is inaccurate because it is not based on real noise energy estimation to adjust the volume table correspondingly.

Therefore, it is necessary to provide improved technology to increase the listening signal-to-noise ratio and bring better sound experience for users.

### SUMMARY

According to one aspect of the disclosure, a method of automatic volume control for a speaker system is provided. The method may comprise: obtaining a microphone input signal including a plurality of frames; performing a filter processing on the microphone input signal to obtain the filtered microphone input signal; estimating an energy value for each frame of the filtered microphone input signal; constructing a first set of data consisting of estimated energy values of a predefined number of frames of the filtered microphone input signal; determining a gain coefficient based on the estimated energy values in the first set; and performing the volume control based on the gain coefficient.

According to another aspect of the present disclosure, a system of automatic volume control for a speaker system is provided. The system may comprise a memory configured to store instructions, and a processor coupled to the memory. The processor may be configured to perform the instructions to obtain a microphone input signal including a plurality of frames; perform a filter processing on the microphone input signal to obtain the filtered microphone input signal; estimate an energy value for each frame of the filtered microphone input signal; construct a first set of data consisting of estimated energy values of a predefined number of frames of the filtered microphone input signal; determine a gain coefficient based on the estimated energy values in the first set; and perform the volume control based on the gain coefficient.

According to yet another aspect of the present disclosure, a non-transitory computer-readable storage medium comprising computer-executable instructions which, when executed by a computer, causes the computer to perform the method disclosed herein.

### BRIEF DESCRIPTION OF THE DRAWINGS

FIG. 1 illustrates a method of automatic volume control for a speaker system according to one or more embodiments of the present disclosure.

FIG. 2 shows a block diagram for illustrating an exemplary process of automatic volume control for a speaker system according to one or more embodiments of the present disclosure.

FIG. 3 illustrates a measurement result of a wind noise detection system according to one or more embodiments of the present disclosure.

FIG. 4 shows a block diagram for illustrating another exemplary process of automatic volume control for a speaker system according to one or more embodiments of the present disclosure.

FIG. 5 illustrates a measurement result of a noise detection system according to one or more embodiments of the present disclosure.

To facilitate understanding, identical reference numerals have been used, where possible, to designate identical elements that are common to the figures. It is contemplated that elements disclosed in one embodiment may be beneficially utilized in other embodiments without specific recitation. The drawings referred to here should not be understood as being drawn to scale unless specifically noted. Also, the drawings are often simplified and details or components omitted for clarity of presentation and explanation. The drawings and discussion serve to explain principles discussed below, where like designations denote like elements.

### DETAILED DESCRIPTION OF THE PREFERRED EMBODIMENTS

Examples will be provided below for illustration. The descriptions of the various examples will be presented for purposes of illustration, but are not intended to be exhaustive or limited to the embodiments disclosed. Many modifications and variations will be apparent to those of ordinary skill in the art without departing from the scope and spirit of the described embodiments.

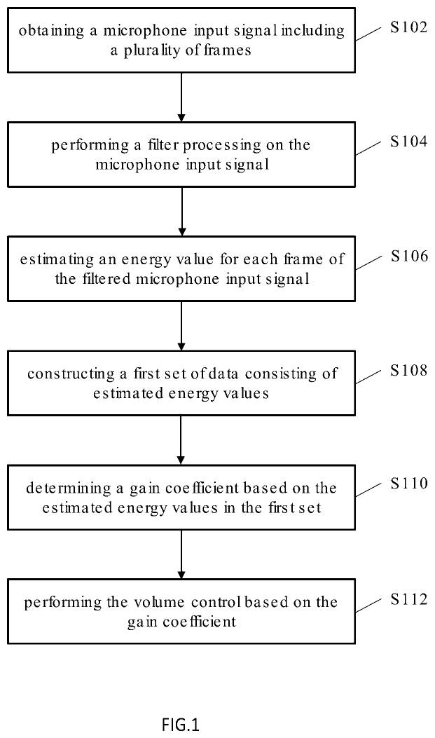

The various embodiments in this disclosure provide a new approach of automatic volume control for a speaker system, which may automatically adjust the speaker's volume based on real-time noise energy estimation. Furthermore, different gain flags for adjusting the volume may be associated with different threshold conditions of noise energy estimation. Thus, the volume control using this method will be more accurate and will bring a better listening experience for users. The method will be explained in detail with reference to FIGS. 1-5 as follows.

FIG. 1 illustrates a method of automatic volume control for a speaker system according to one or more embodiments of the present disclosure. In some embodiments, at step 102, a microphone input signal including a plurality of frames may be obtained. In some examples, the microphone input signal may include wind noise. In other examples, the microphone input signal may include other ambient noise in addition to wind noise.

At S104, a filer processing may be performed on the microphone input signal. For example, the microphone input signal may be filtered by a low-pass filter to extract low-frequency energy features.

At S106, for each frame of filtered microphone input signal, an energy value may be estimated. At S108, a set of estimated energy values may be constructed. The size of the set of estimated energy values may be predefined according to different design requirements. In other words, the set of estimated energy may be a vector consisting of a predefined number of frames of the filtered microphone input signal, according to different design requirements.

At S110, based on the estimated energy values in the set, a gain coefficient may be determined. In some embodiments, a plurality of threshold conditions may be predefined. By determining which one threshold condition may be met according to the estimated energy values in the set, a corresponding gain flag may be determined. In some examples, the determined gain flag may be directly set to the gain coefficient. In other examples, the determined gain flag may be further smoothed based on the currently determined gain flag and at least one previously determined gain flag. Then, the smoothed gain flag may be set to the gain coefficient. At S112, the gain coefficient may be applied to the audio chain for automatic volume control.

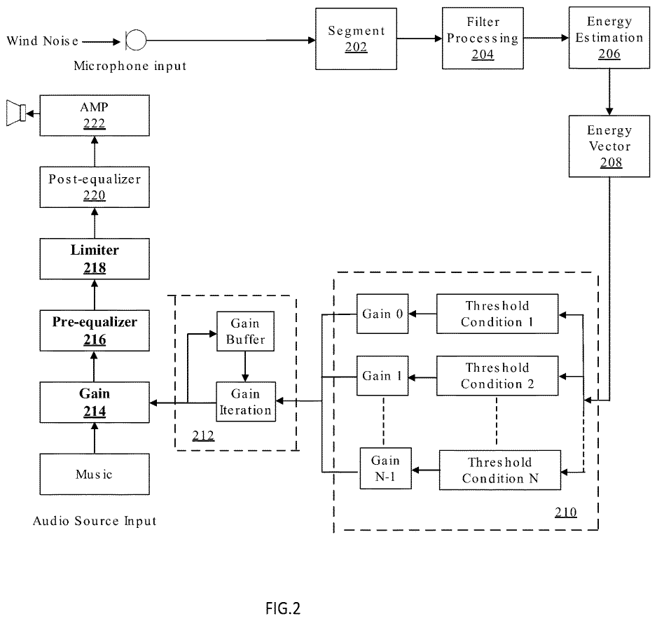

FIG. 2 shows a block diagram for illustrating an exemplary process of automatic volume control for a speaker system according to one or more embodiments of the present disclosure. As discussed above, based on existing research in the art, it has been known that the pressure spectrum of wind in small Reynolds number turbulent flows approaches a constant in the lower frequency range and decays rapidly in the higher frequency range. Reynolds number is a dimensionless number used to characterize fluid flow conditions. Based on the pressure spectrum feature of wind noise, we will first discuss a system in reference to FIG. 2, which detects wind noise energy and adjusts volume automatically based on the detected wind noise energy.

FIG. 2 illustrates the exemplary process of adjusting the volume of the speaker system based on wind noise estimation in the form of signal flow. As shown in FIG. 2, a microphone may be configured to capture wind noise. Assumed that microphone captured signal is expressed as x(k). At block 202, the microphone captured signal may be segmented into frames, and then a microphone input signal including a plurality of frames may be obtained. Each frame may include a lot of samples. For example, the m-th frame of the microphone input signal may be expressed as [x(0, m),x(1, m), x(2, m), . . . , x(L−1, m)], wherein L is the frame length in unit of samples. The m-th frame formula can be expressed as follows.

$$y ( m ) = {\sum }_{l = 0}^{L - 1} x ( l , m ) \qquad ( 1 )$$

At block 204, a filter processing may be performed on each frame of the microphone input signal to obtain filtered frames of the filtered microphone input signal. In some examples, the filter processing may be performed by a low-pass filter.

At block 206, an energy estimation for each filtered frame (i.e., each frame of the filtered microphone input signal) may be calculated. For example, the energy of the m-th frame of the filtered microphone input signal can be calculated as below.

$$E ( m ) = {\sum }_{l = 0}^{L - 1} {[ x ( l , m ) ]}^{2} \qquad ( 2 )$$

At block 208, a buffer vector of energy may be constructed. For example, the buffer vector of energy can be written as follows.

E_{bf}=[E(1),E(2), . . . ,E(M)] (3)

wherein M is the total interesting frame number, which can be predefined according to system design requirement. In other words, the buffer vector is a set of estimated energy that includes estimated energy values of a predefined number of frames.

In some embodiments, for better robustness, each estimated energy E(m) may be smoothed before constructing the buffer vector. The smooth process may be expressed as follows.

$$\{ \begin{matrix}{E}_{sm} ( m ) = α * {E}_{sm} ( m - 1 ) + ( 1 - α ) * E ( m ) , {E}_{sm} ( m - 1 ) < E ( m ) \\ {E}_{sm} ( m ) = β * {E}_{sm} ( m - 1 ) + ( 1 - β ) * E ( m ) , {E}_{sm} ( m - 1 ) \geq E ( m )\end{matrix} \qquad ( 4 )$$

wherein Eₛₘ(m) represents the smoothed energy for the m-th frame, and both α and β are smoothing factors and their ranges are both from 0 to 1. The previous m-th frame of smoothed energy can be expressed as Eₛₘ(M−m).

In some examples, the smooth process may comprise comparing, for each frame, the estimated energy for the current frame E(m) with the smoothed energy for the previous frame Eₛₘ(m−1). If the current frame E(m) is larger than the smoothed energy for the previous frame Eₛₘ(m−1), then the smoothed energy for the current frame Eₛₘ(m) is set to be equal to α*Eₛₘ(m−1)+ (1−α)*E(m). Otherwise, the smoothed energy for the current frame Eₛₘ(m) is set to be equal to β*Eₛₘ(m−1)+ (1−β)*E(m). The calculated Eₛₘ(m) may be stored and may be used as an original value for smoothing the energy for the next frame.

Now, the buffer vector of smoothed energy E_{bf} at block 208 can be written as follows.

E_{bf}=[Eₛₘ(1),Eₛₘ(2), . . . ,Eₛₘ(M)] (5)

At block 210, a gain coefficient may be determined based on the smoothed energy values in the buffer vector E_{bf}. The determination process may be defined as below.

$${G}_{flag} ( N ) = \{ \begin{matrix}{r}_{{ul}_{0}} , & if any ( {E}_{bf} ) < {E}_{i {n}_{1}} \\ min ( {r}_{sc} , {r}_{{ul}_{1}} ) , & if all ( {E}_{bf} ) \geq {E}_{i {n}_{1}} , any ( {E}_{bf} ) < {E}_{i {n}_{2}} \\ min ( {r}_{sc} , {r}_{{ul}_{2}} ) , & if all ( {E}_{bf} ) \geq {E}_{i {n}_{2}} , any ( {E}_{bf} ) < {E}_{i {n}_{3}} \\ & ⋮ \\ {r}_{{ul}_{N - 1}} , & i f all ( {E}_{bf} ) \geq {E}_{in \_ N}\end{matrix} , N = 1 , 2 , ⋯ \qquad ( 6 )$$

wherein N is the number of gain flags which may be predefined according to the system requirement. The expression Eᵢₙ may represent a set of energy thresholds and may have N stepwise increasing values, i.e., Eᵢₙ_{₁}, Eᵢₙ_{₂}, . . . , Eᵢₙ_{_{_N}}, which may be initial thresholds of energy as reference. The energy thresholds Eᵢₙ_{₁}, Eᵢₙ_{₂}, . . . , Eᵢₙ_{_{_N}} are configurable in such a way as to support various applications and products. The energy thresholds can be predefined and can be tuned by corresponding training datasets. The expression rᵤₗ may represent a set of reference scale coefficients and may have N stepwise increasing values, i.e., rᵤₗ_{₀}, Tᵤₗ_{₁} . . . , Fᵤₗ_{_{N-1}}. The values of rᵤₗ_{₀}, rᵤₗ_{₁} . . . , rᵤₗ_{_{N-1}} may be predefined respectively. For example, the value of rᵤₗ_{₀} is usually a default constant defined as 1 and the value of rᵤₗ_{_{N-1}} is an interesting upper gain limit. It can be seen from the equation (6) that there is one-to-one mapping between the energy thresholds Eᵢₙ_{₁}, Eᵢₙ_{₂}, . . . , Eᵢₙ_{_{_N}} and the reference scale coefficients rᵤₗ_{₀}, rᵤₗ_{₁} . . . , rᵤₗ_{_{N-1}}.

The parameter r_{sc} in the equation (6) represents an estimated scale coefficient, which may be calculated based on an average of the estimated energy values in the buffer vector E_{bf} and a corresponding threshold energy (i.e., one of energy thresholds Eᵢₙ_{₁}, Eᵢₙ_{₂}, . . . , Eᵢₙ_{_{N}}). The parameter r_{sc} reflects a proportion of the current energy to the initially defined energy threshold. For example, the average Eave may be expressed as follows.

$${E}_{ave} = \frac{1}{M} {\sum }_{m = 0}^{M} {E}_{sm} ( m ) \qquad ( 7 )$$

Then, r_{sc} may be expressed as follows.

$${r}_{sc} = \frac{{E}_{ave}}{{E}_{i n}} \qquad ( 8 )$$

It can be understood from the equation (6) that a plurality of threshold conditions may be defined for the determination process of gain coefficient. By determining which threshold condition is met based on the estimated energy values in the buffer vector E_{bf}, the corresponding gain flag can be obtained.

In some examples, as for the first threshold condition (Threshold 1), it determines if any one of the estimated energy values in the set E_{bf} is less than the minimum energy threshold Eᵢₙ_{₁}. If yes, the gain flag is determined to be equal to the minimum reference scale coefficient rᵤₗ_{₀}. If no, then the determination process may move to the second threshold condition (Threshold 2). The second threshold condition is used to determine if all the estimated energy values in the set E_{bf} are greater than or equal to the energy threshold Eᵢₙ, and if any one of the estimated energy values in the set E_{bf} is less than the energy threshold Eᵢₙ_{₂}. If yes, the gain flag is determined to be equal to the minimum between the reference scale coefficient rᵤₗ_{₁} and the estimated scale coefficient r_{sc}, wherein the estimated scale coefficient r_{sc} may be calculated based on the average Eave and the corresponding energy threshold Eᵢₙ_{₂}. If no, then the determination process may move to the third threshold condition (Threshold 3). The determine process is continued in a similar way until the N-th threshold condition is reached. The N-th threshold condition is used to determine if all the estimated energy values in the set E_{bf} are less than or equal to the energy threshold Eᵢₙ_{_{N}} (i.e., the maximum energy threshold).

In some embodiments, the determined gain flag at block 210 may be directly used as the gain coefficient for adjusting the speaker system's volume. For example, the determined gain flag at block 210 as the gain coefficient may be directly applied to audio chain (for example, the determined gain flag may be directly input to block 214) to adjust the gain of the audio signal in the audio chain. In some embodiments, the determined gain flag at block 210 may be input to block 212 and may be smoothed at the block 212, in order to avoid bad hearing experience caused by sudden increase of energy.

Blocks 214-222 in FIG. 2 illustrate a general audio chain from an audio source input to a speaker output. The gain, pre-equalizer, limiter, post-equalizer and amplifier (AMP) are usually-used means for the skilled person in the art, which are shown here only for the purpose of explanation. These blocks may be implemented by software, hardware or combination thereof, as known by the skilled person in the art.

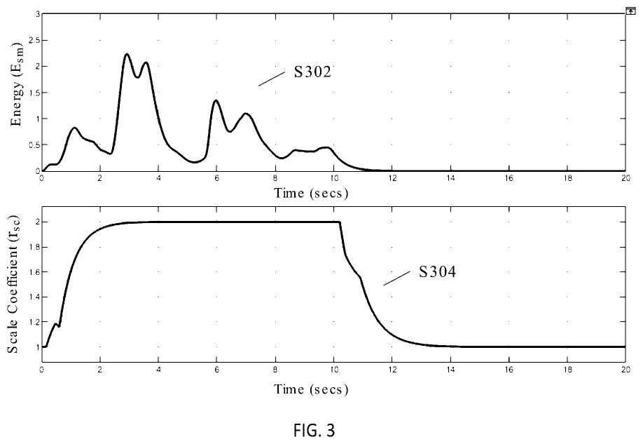

In order to measure the effect of the volume control method based on the energy estimation of wind noise described above in reference to FIGS. 1-2, a wind noise detection system using the discussed method is set up. The wind noise detection system includes a speaker with a single microphone and a blower used to generate stable wind. The measurement result of the wind noise detection system is shown in FIG. 3. From the curves 302 and 304 in FIG. 3, it can be known that the blower starts to generate wind in the time of 0.2 s. When the system detects wind noise, it does work and it can be seen that the scale coefficient r_{sc} is slowly increasing to the interesting upper gain limit (r_{sc}=2) within about 3 s. The scale coefficient r_{sc} keeps at the upper gain limit within the next 7 s because wind exists. When the wind fades away at about 10 s, r_{sc} slowly returns to the default value 1. It can be concluded that this system can automatically adjust speaker volume based on wind noise energy estimation.

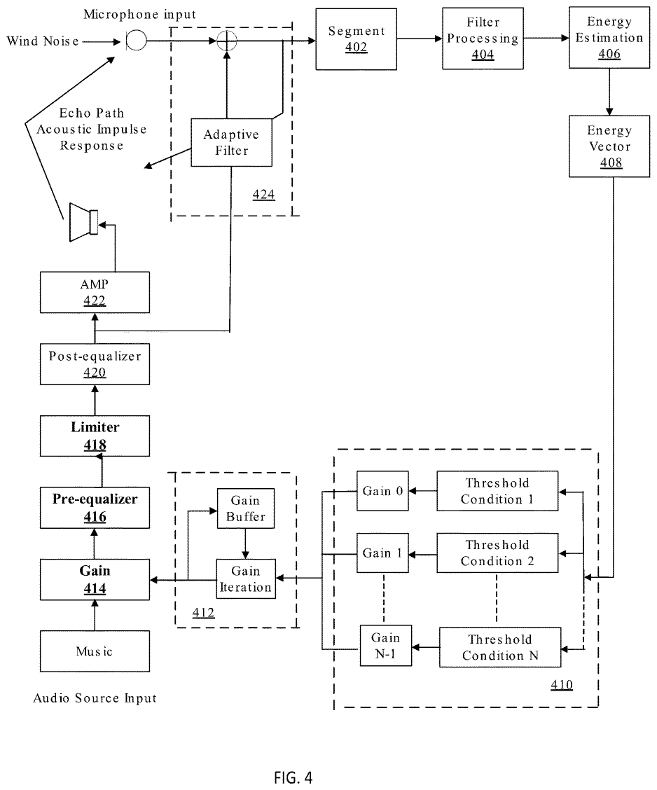

FIG. 4 illustrates an exemplary process of adjusting the volume of the speaker system based on noise estimation, which is modified from that illustrated in FIG. 2. The functions of blocks 402-422 FIG. 4 are the same as the blocks 202-222 in FIG. 2. Thus, the description thereof will be omitted here. The process shown in FIG. 4 additionally includes an AEC (Acoustic Echo Cancellation) module 424, which is used to remove local music signals from the speaker and get correspondingly pure ambient noise accordingly. For an AEC method, a frequency domain adaptive filter may be applied due to its good performance and fast rate of convergence. AEC technology has been a mature and commonly used technology in the audio field. It can be understood by those skilled in the art that any existing AEC can be applied to the module of the present invention. By applying the method discussed above in this disclosure to the system shown in FIG. 4, variations in ambient noise can be compensated, not only for wind noise. The noise detection system shown in FIG. 4 may also be accurate to adjust speaker volume automatically based on noise energy estimation.

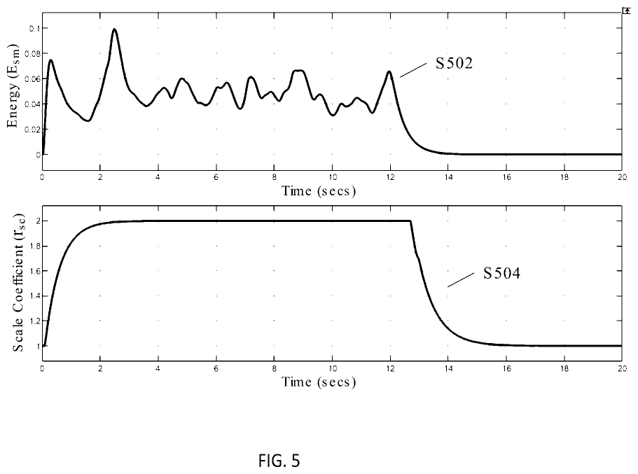

In order to measure the effect of the volume control method based on the energy estimation of wind noise described above in reference to FIGS. 1 and 4, a noise detection system using the discussed method is set up. The noise detection system includes a speaker with a single microphone and another external speaker is used to play noise. The measurement result of the noise detection system is shown in FIG. 5. From the curves 502 and 504 in FIG. 5, it can be known that speaker volume can increase to the target (i.e., interesting upper gain limit r_{sc}=2) with the ambient noise rising and slowly return to default when noise disappears. It is obvious that the noise detection system can obtain the same result as the wind noise detection system when the speaker is in a noisy ambient environment.

It can be recognized that the discussed method above may be realized by a processor included in the speaker system. The speaker system may comprise a memory and a processor. The memory may be configured to store computer-readable instructions or codes for causing the processor to carry out the above said aspects of the present disclosure. The processor may be any technically feasible hardware unit configured to process data and execute software applications, including without limitation, a central processing unit (CPU), a microcontroller unit (MCU), an application specific integrated circuit (ASIC), a digital signal processor (DSP) chip and so forth.

The descriptions of the various embodiments have been presented for purposes of illustration, but are not intended to be exhaustive or limited to the embodiments disclosed. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the preceding features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module”, “unit” or “system.”

The present disclosure may be a system, a method, and/or a computer program product. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective calculating/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

The flowchart and block diagrams in the drawings illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to embodiments of the present disclosure, other and further embodiments of the disclosure may be devised without departing from the basic scope thereof, and the scope thereof is determined by the claims that follow.

Clause 1. In some embodiments, a method of automatic volume control for a speaker system comprising: obtaining a microphone input signal including a plurality of frames; performing a filter processing on the microphone input signal to obtain the filtered microphone input signal; estimating an energy value for each frame of the filtered microphone input signal; constructing a first set of data consisting of estimated energy values of a predefined number of frames of the filtered microphone input signal; determining a gain coefficient based on the estimated energy values in the first set; and performing the volume control based on the gain coefficient.

Clause 2. The method according to clause 1, wherein the determining the gain coefficient based on the estimated energy values in the first set comprises determining, based on the estimated energy values in the first set, which threshold condition of a plurality of threshold conditions is met; obtaining a gain flag corresponding to the determined threshold condition; and setting the gain flag to the gain coefficient.

Clause 3. The method according to any one of clauses 1-2, wherein the plurality of threshold conditions are associated with a second set of data that consists of energy thresholds with stepwise increasing values.

Clause 4. The method according to any one of clauses 1-3, wherein the gain flag is associated with a third set of data and an estimated scale coefficient, wherein the third set of data consists of reference scale coefficients with stepwise increasing values.

Clause 5. The method according to any one of clauses 1-4, wherein the estimated scale coefficient is calculated by calculating an average of the estimated energy values in the first set and calculating a corresponding estimated scale coefficient based on the calculated average and a corresponding energy threshold from a second set.

Clause 6. The method according to any one of clauses 1-5, wherein there is one-to-one mapping between the energy thresholds in the second set and the reference scale coefficients in the third set.

Clause 7. The method according to any one of clauses 1-6, further comprising smoothing the estimated energy value for each frame.

Clause 8. The method according to any one of clauses 1-7, further comprising smoothing the gain flag before setting the gain flag to the gain coefficient, wherein the smoothing is based on a current gain flag and at least one previous gain flag.

Clause 9. The method according to any one of clauses 1-8, wherein the microphone input signal includes at least one of wind noise and ambient noise.

Clause 10. In some embodiments, a system of automatic volume control for a speaker system comprising: a memory configured to store instructions; and a processor configured to perform the instructions to: obtain a microphone input signal including a plurality of frames; perform a filter processing on the microphone input signal to obtain the filtered microphone input signal; estimate an energy value for each frame of the filtered microphone input signal; construct a first set of data consisting of estimated energy values of a predefined number of frames of the filtered microphone input signal; determine a gain coefficient based on the estimated energy values in the first set; and perform the volume control based on the gain coefficient.

Clause 11. The system according to clause 10, wherein the processor is further configured to: determine, based on the estimated energy values in the first set, which threshold condition of a plurality of threshold conditions is met; obtain a gain flag corresponding to the determined threshold condition; and set the gain flag to the gain coefficient.

Clause 12. The system according to any one of clauses 10-11, wherein the plurality of threshold conditions are associated with a second set of data that consists of energy thresholds with stepwise increasing values.

Clause 13. The system according to any one of clauses 10-12, wherein the gain flag is associated with a third set of data and an estimated scale coefficient, wherein the third set of data consists of reference scale coefficients with stepwise increasing values.

Clause 14. The system according to any one of clauses 10-13, wherein the estimated scale coefficient is calculated by calculating an average of the estimated energy values in the first set and calculating a corresponding estimated scale coefficient based on the calculated average and a corresponding energy threshold from a second set.

Clause 15. The system according to any one of clauses 10-14, wherein there is one-to-one mapping between the energy thresholds in the second set and the reference scale coefficients in the third set.

Clause 16. The system according to any one of clauses 10-15, wherein the processor is further configured to smooth the estimated energy value for each frame.

Clause 17. The system according to any one of clauses 10-16, wherein the processor is further configured to smooth the gain flag based on a current gain flag and at least one previous gain flag before setting the gain flag to the gain coefficient.

Clause 18. In some embodiments, a non-transitory computer-readable storage medium comprising computer-executable instructions which, when executed by a computer, causes the computer to perform the method according to any one of claims 1-9.

1. A method of automatic volume control for a speaker system comprising:
obtaining a microphone input signal including a plurality of frames;
performing filter processing on the microphone input signal to obtain the filtered microphone input signal;
estimating an energy value for each frame of the filtered microphone input signal;
constructing a first set of data consisting of estimated energy values of a predefined number of frames of the filtered microphone input signal;
determining a gain coefficient based on the estimated energy values in the first set; and
performing the volume control based on the gain coefficient.

2. The method according to claim 1, wherein the determining the gain coefficient based on the estimated energy values in the first set comprises:
determining, based on the estimated energy values in the first set, which threshold condition of a plurality of threshold conditions is met;
obtaining a gain flag corresponding to the determined threshold condition; and
setting the gain flag to the gain coefficient.

3. The method according to claim 2, wherein the plurality of threshold conditions are associated with a second set of data that consists of energy thresholds with stepwise increasing values.

4. The method according to claim 3, wherein the gain flag is associated with a third set of data and an estimated scale coefficient, wherein the third set of data consists of reference scale coefficients with stepwise increasing values.

5. The method according to claim 4, wherein the estimated scale coefficient is calculated by
calculating an average of the estimated energy values in the first set; and
calculating a corresponding estimated scale coefficient based on the calculated average and a corresponding energy threshold from a second set.

6. The method according to claim 4, wherein there is one-to-one mapping between the energy thresholds in the second set and the reference scale coefficients in the third set.

7. The method according to claim 1, further comprising smoothing the estimated energy value for each frame.

8. The method according to claim 2, further comprising smoothing the gain flag before setting the gain flag to the gain coefficient, wherein the smoothing is based on a current gain flag and at least one previous gain flag.

9. The method according to claim 1, wherein the microphone input signal includes at least one of wind noise and ambient noise.

10. A system of automatic volume control for a speaker system comprising:
a memory configured to store instructions; and
a processor configured to perform the instructions to:
obtain a microphone input signal including a plurality of frames;
perform filter processing on the microphone input signal to obtain the filtered microphone input signal;
estimate an energy value for each frame of the filtered microphone input signal;
construct a first set of data consisting of estimated energy values of a predefined number of frames of the filtered microphone input signal;
determine a gain coefficient based on the estimated energy values in the first set; and
perform the volume control based on the gain coefficient.

11. The system according to claim 10, wherein the processor is further configured to:
determine, based on the estimated energy values in the first set, which threshold condition of a plurality of threshold conditions is met;
obtain a gain flag corresponding to the determined threshold condition; and
set the gain flag to the gain coefficient.

12. The system according to claim 11, wherein the plurality of threshold conditions are associated with a second set of data that consists of energy thresholds with stepwise increasing values.

13. The system according to claim 12, wherein the gain flag is associated with a third set of data and an estimated scale coefficient, wherein the third set of data consists of reference scale coefficients with stepwise increasing values.

14. The system according to claim 13, wherein the estimated scale coefficient is calculated by the following:
calculating an average of the estimated energy values in the first set; and
calculating a corresponding estimated scale coefficient based on the calculated average and a corresponding energy threshold from a second set.

15. The system according to claim 13, wherein there is one-to-one mapping between the energy thresholds in the second set and the reference scale coefficients in the third set.

16. The system according to claim 10, wherein the processor is further configured to smooth the estimated energy value for each frame.

17. The system according to claim 11, wherein the processor is further configured to smooth the gain flag based on a current gain flag and at least one previous gain flag before setting the gain flag to the gain coefficient.

18. A non-transitory computer-readable storage medium comprising computer-executable instructions which, when executed by a computer, causes the computer to perform the method:
obtaining a microphone input signal including a plurality of frames;
performing filter processing on the microphone input signal to obtain the filtered microphone input signal;
estimating an energy value for each frame of the filtered microphone input signal;
constructing a first set of data consisting of estimated energy values of a predefined number of frames of the filtered microphone input signal;
determining a gain coefficient based on the estimated energy values in the first set; and
performing the volume control based on the gain coefficient.

19. The medium according to claim 18, wherein the determining the gain coefficient based on the estimated energy values in the first set comprises:
determining, based on the estimated energy values in the first set, which threshold condition of a plurality of threshold conditions is met;
obtaining a gain flag corresponding to the determined threshold condition; and
setting the gain flag to the gain coefficient.

20. The medium according to claim 19, wherein the plurality of threshold conditions are associated with a second set of data that consists of energy thresholds with stepwise increasing values.
